(19) United States
(12) Patent Application Publication
(10) Pub. No.: US 2006/0273413 A1
(43) Pub. Date: Dec. 7, 2006

(54) Semiconductor device and method of manufacturing the same

(76) Inventors: Motoyuki Sato, Yokohama-Shi (JP); Katsuyuki Sekine, Yokohama-Shi (JP); Kazuaki Nakajima, Kamakura-Shi (JP); Tomohiro Saito, Yokohama-Shi (JP); Kazuhiro Eguchi, Chigasaki-Shi (JP); Atsushi Yagishita, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/185,678

(22) Filed: Jul. 21, 2005

(30) Foreign Application Priority Data
Jun. 3, 2005 (JP) 2005-164179

(51) Int. Cl. H01L 29/94

(52) U.S. Cl. 257/411

(57) ABSTRACT

There are provided: a semiconductor substrate including first and second device regions isolated by device isolation regions; a first gate insulating film of a high-k material formed in the first device region; a first gate electrode formed on the first gate insulating film; first source and drain regions formed at both sides of the first gate electrode in the first device region; a second gate insulating film of a high-k material which is different from the high-k material of the first gate insulating film, the second gate insulating film being formed in the second device region; a second gate electrode formed on the second gate insulating film; and second source and drain regions formed at both sides of the second gate electrode in the second device region.

### CROSS-REFERENCE TO RELATED APPLICATION

This application is based upon and claims the benefit of priority from prior Japanese Patent Application No. 2005-164179, filed on Jun. 3, 2005 in Japan, the entire contents of which are incorporated herein by reference.

### BACKGROUND OF THE INVENTION

1. Field of the Invention

The present invention relates to a semiconductor device and a method of manufacturing the same.

2. Background Art

Recently, the miniaturization of semiconductor devices (for example, MIS transistors) has been advancing and as a result, the thickness of a gate insulating film formed of SiO₂ or SiON is required to be decreased. However, when the thickness of a gate insulating film is decreased, a problem arises that the degree of leak current is increased. Accordingly, a gate insulating film formed of a high-k material, in which the actual physical thickness is thick and the EOT (Equivalent Oxide Thickness) is thin, is being developed.

Furthermore, a demand for a semiconductor device, which includes circuits each having a different function (for example, a memory and a logic circuit) formed on the same substrate, is growing. A MOS transistor used as a memory is required to have a small degree of leak current from a gate insulating film, so that the power consumption can be decreased. In contrast with this, a MOS transistor used as a logic circuit is required to operate at a high speed.

Accordingly, an insulating film formed of a single layer of high-k material is considered to be used as a gate insulating film of a MOS transistor used in a memory, and an insulating film formed by stacking a high-k insulating layer on an insulating layer of SiO₂ or SiON is considered to be used as a gate insulating film of a MOS transistor used as a logic circuit.

A technique is known in which a gate electrode including the aforementioned gate insulating film formed of a single layer of a high-k material and a gate electrode including the aforementioned gate insulating film formed by stacking a high-k insulating layer on a silicon oxide layer are formed on the same substrate (for example, U.S. Pat. No. 6,670,248). In this technique, first a silicon oxide layer is formed on a substrate, then a resist pattern is formed on the silicon oxide layer, and then the silicon oxide layer is patterned using the resist pattern as a mask. Thereafter, the resist pattern is removed, a high-k insulating layer is formed on the entire substrate, and a polycrystalline silicon film is formed on the high-k insulating layer. Subsequently, the polycrystalline silicon film, the high-k insulating layer, and the silicon oxide layer are patterned using the lithography technique, thereby forming a gate electrode including a gate insulating film formed of a single high-k insulating layer and a gate electrode including a gate insulating film formed by stacking a silicon oxide layer and a high-k insulating layer on the same substrate.

However, in the aforementioned gate insulating film, in which a high-k insulating layer is stacked on a silicon oxide layer, before the high-k insulating layer is stacked, the silicon oxide layer is patterned using a resist pattern, and then the resist pattern is removed. There is a problem in that at the time of the removing of the resist pattern, the upper surface of the silicon oxide layer is damaged, thereby degrading the condition of the interface between the silicon oxide layer and the high-k insulating layer, resulting in that the device characteristics are degraded.

Thus, when a device (MOS transistor) includes gate insulating films each being formed of a different material but being formed on the same substrate, there is a problem in that the device characteristics may be degraded.

### SUMMARY OF THE INVENTION

A semiconductor device according to a first aspect of the present invention includes: a semiconductor substrate including first and second device regions isolated by device isolation regions; a first gate insulating film of a high-k material formed in the first device region; a first gate electrode formed on the first gate insulating film; first source and drain regions formed at both sides of the first gate electrode in the first device region; a second gate insulating film of a high-k material which is different from the high-k material of the first gate insulating film, the second gate insulating film being formed in the second device region; a second gate electrode formed on the second gate insulating film; and second source and drain regions formed at both sides of the second gate electrode in the second device region.

A semiconductor device according to a second aspect of the present invention includes: a semiconductor substrate including first and second device regions isolated by device isolation regions; a first channel region formed in the first device region; first source and drain regions provided at both sides of the first channel region in the first device region; a first interlayer insulating film covering the first source and drain regions but including a first opening which is provided above the first channel region so as to expose the first channel region at a bottom thereof; a first gate insulating film of a high-k material provided at the bottom and side portions of the first opening; a first gate electrode covering the first gate insulating film in the first opening; a second channel region provided in the second device region; second source and drain regions provided at both sides of the second device region in the second channel region; a second interlayer insulating film covering the second source and drain regions but including a second opening which is provided above the second channel region so as to expose the second channel region at a bottom thereof; a second gate insulating film of a high-k material which is different from the high-k material of the first gate insulating film, the second gate insulating film being provided at the bottom and side portions of the second opening; and a second gate electrode covering the second gate insulating film in the second opening.

A method of manufacturing a semiconductor device according to a third aspect of the present invention includes: forming a first insulating film of a high-k material on first and second device regions of a semiconductor substrate which are isolated by device isolation regions; forming a first electrode material film on the first insulating film; forming a second insulating film on the first electrode material film; removing the second insulating film, the first electrode material film and the first insulating film on the second device region; forming a third insulating film of a high-k material, which is different from the high-k material of the first insulating film, on the second device region; depositing a second gate electrode material film on the first and second device region; removing the second gate electrode material film and the second insulating film on the first device region by flattening the second gate electrode material film; forming first and second gate electrodes by patterning the first and second gate electrode material films; and forming first and second gate insulating films by patterning the first and third insulating films using the first and second gate electrodes as masks.

A method of manufacturing a semiconductor device according to a fourth aspect of the present invention includes: forming first and second dummy gate electrodes on first and second device regions of a semiconductor substrate which are isolated by device isolation regions; forming first source and drain regions at both sides of the first dummy gate electrode in the first device region, and at the same time forming second source and drain regions at both sides of the second dummy gate electrode in the second device region; depositing an interlayer insulating film to cover the first and second device region; forming first and second opening portions reaching the first and second device regions through the interlayer insulating film by removing the first and second dummy gate electrodes; forming first gate insulating film at a bottom and side portions of the first opening portion; forming a first gate electrode covering the first gate insulating film in the first opening portion; forming a second gate insulating film at a bottom and side portions of the second opening portion; and forming a second gate electrode covering the second gate insulating film in the second opening portion.

### BRIEF DESCRIPTION OF THE DRAWINGS

FIG. 1 is a sectional view showing a step of a method of manufacturing a semiconductor device according to the first embodiment of the present invention.

FIG. 2 is a sectional view showing a step of the method of manufacturing a semiconductor device according to the first embodiment of the present invention.

FIG. 3 is a sectional view showing a step of the method of manufacturing a semiconductor device according to the first embodiment of the present invention.

FIG. 4 is a sectional view showing a step of the method of manufacturing a semiconductor device according to the first embodiment of the present invention.

FIG. 5 is a sectional view showing a step of the method of manufacturing a semiconductor device according to the first embodiment of the present invention.

FIG. 6 is a sectional view showing a step of the method of manufacturing a semiconductor device according to the first embodiment of the present invention.

FIG. 7 is a sectional view showing a step of the method of manufacturing a semiconductor device according to the first embodiment of the present invention.

FIG. 8 is a sectional view showing a step of the method of manufacturing a semiconductor device according to the first embodiment of the present invention.

FIG. 9 is a sectional view showing a step of the method of manufacturing a semiconductor device according to the first embodiment of the present invention.

FIG. 10 is a sectional view showing a step of the method of manufacturing a semiconductor device according to the first embodiment of the present invention.

FIG. 11 is a sectional view showing a step of the method of manufacturing a semiconductor device according to the first embodiment of the present invention.

FIG. 12 is a sectional view showing a step of the method of manufacturing a semiconductor device according to the first embodiment of the present invention.

FIG. 13 is a sectional view showing a step of a method of manufacturing a semiconductor device according to the second embodiment of the present invention.

FIG. 14 is a sectional view showing a step of the method of manufacturing a semiconductor device according to the second embodiment of the present invention.

FIG. 15 is a sectional view showing a step of the method of manufacturing a semiconductor device according to the second embodiment of the present invention.

FIG. 16 is a sectional view showing a step of the method of manufacturing a semiconductor device according to the second embodiment of the present invention.

FIG. 17 is a sectional view showing a step of the method of manufacturing a semiconductor device according to the second embodiment of the present invention.

FIG. 18 is a sectional view showing a step of the method of manufacturing a semiconductor device according to the second embodiment of the present invention.

FIG. 19 is a sectional view showing a step of the method of manufacturing a semiconductor device according to the second embodiment of the present invention.

FIG. 20 is a sectional view showing a step of the method of manufacturing a semiconductor device according to the second embodiment of the present invention.

### DESCRIPTION OF THE EMBODIMENTS

Hereinafter, embodiments of the present invention will be described with reference to the accompanying drawings.

### First Embodiment

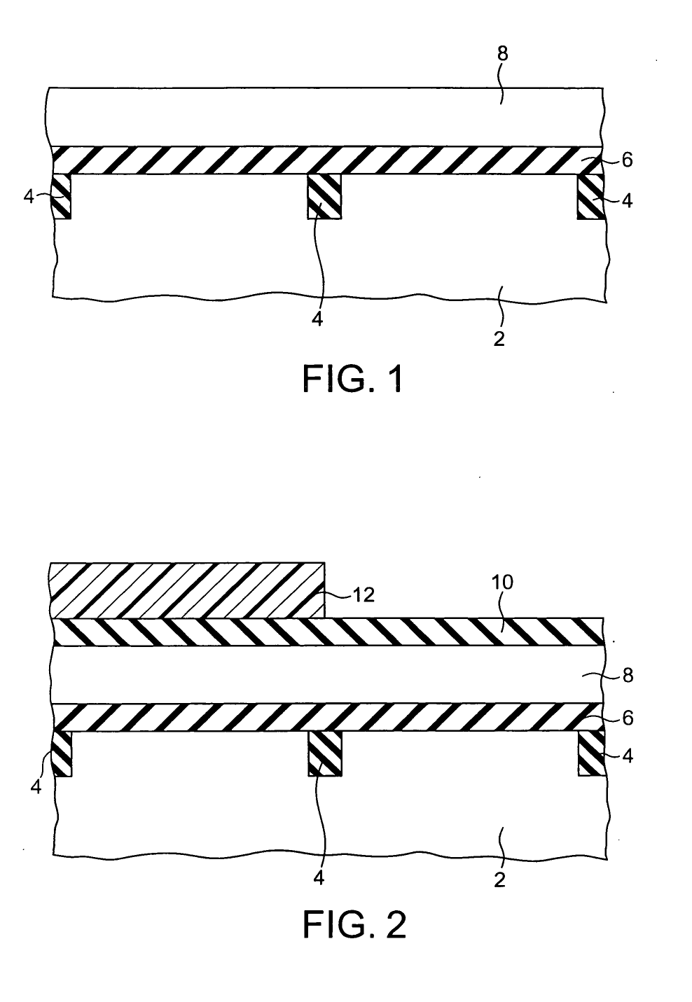

A method of manufacturing a semiconductor device according to the first embodiment of the present invention will be described below with reference to FIGS. 1 to 12, which are sectional views showing the steps of the manufacturing method according to this embodiment.

First, as shown in FIG. 1, an insulating film 6 of HfSiON, i.e., a high-k material, is formed on a semiconductor substrate 2, having a first device region and a second device region isolated by device isolation regions 4. Subsequently, a gate electrode material film 8 formed of, for example, polycrystalline silicon is formed on the insulating film 6. The gate electrode material film 8 cam be formed of a fully-silicided layer or a metal layer instead of a polycrystalline silicon layer.

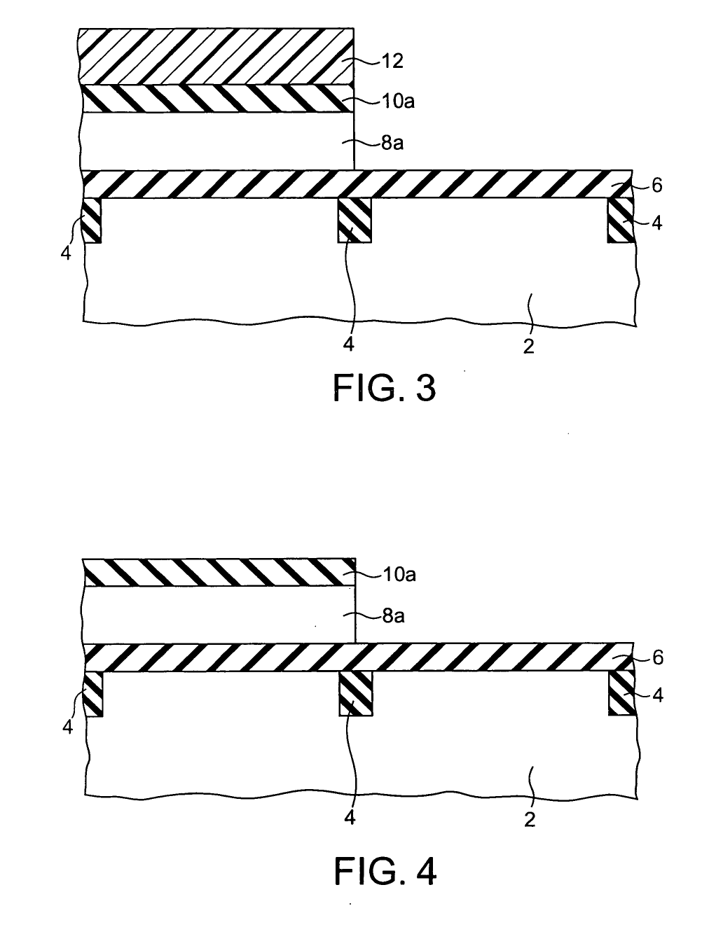

Next, an insulating film 10 of SiO₂ or SiN is formed on the gate electrode material film 8. The insulating film 10 serves as a stopper when CMP (Chemical Mechanical Polishing) is performed in a later stage (FIG. 2). Subsequently, a resist pattern 12 of a photoresist is formed on the insulating film 10 (FIG. 2). Then, the insulating film 10 and the gate electrode material film 8 are patterned by, for example, radical dry etching using the resist pattern 12 as a mask, thereby leaving a gate electrode material film 8a and an insulating film 10a in the first device region, but removing the insulating film 10 and the gate electrode material film 8 in the second device region to expose the surface of the insulating film 6 (FIG. 3). Instead of radical dry etching, chemical dry etching or wet etching can be used to pattern the gate electrode material film 8 of polycrystalline silicon.

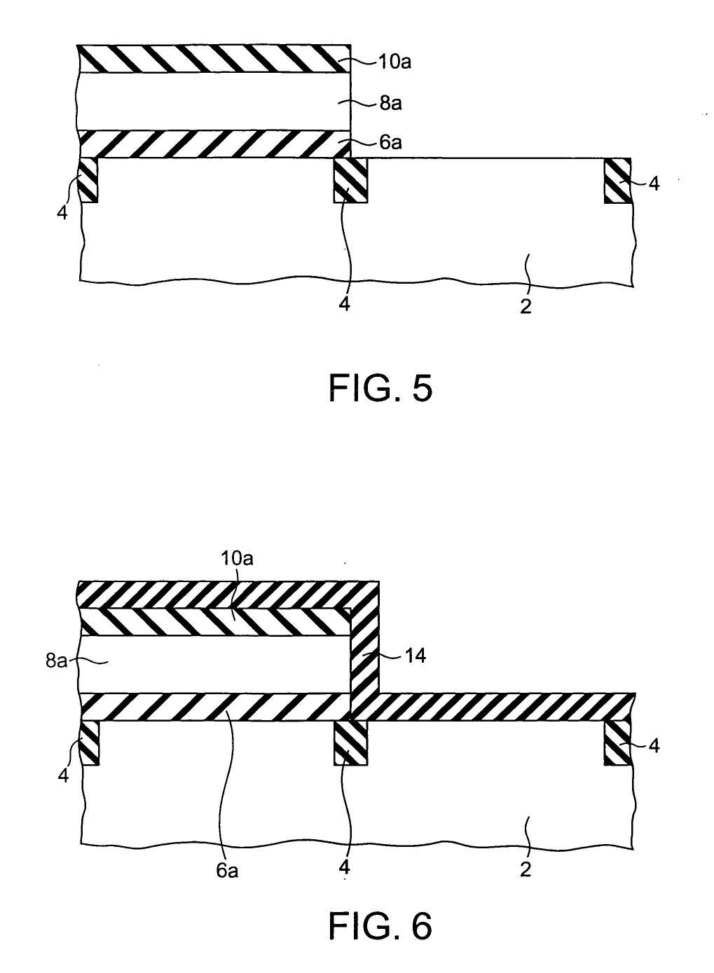

Then, the resist pattern 12 is removed (FIG. 4). Subsequently, the insulating film 6 of HfSiON, which is exposed in the second device region, is removed by, for example, wet etching. At this time an insulating film 6a is left only in the first device region (FIG. 5).

Next, as shown in FIG. 6, an insulating film 14 of HfSiON, the Hf concentration of which differs from that of the insulating film 6, is formed on the entire surface. At this time, the insulating film 14 of HfSiON is formed not only on the substrate in the second device region but also above and at the side of the gate electrode material film 8a.

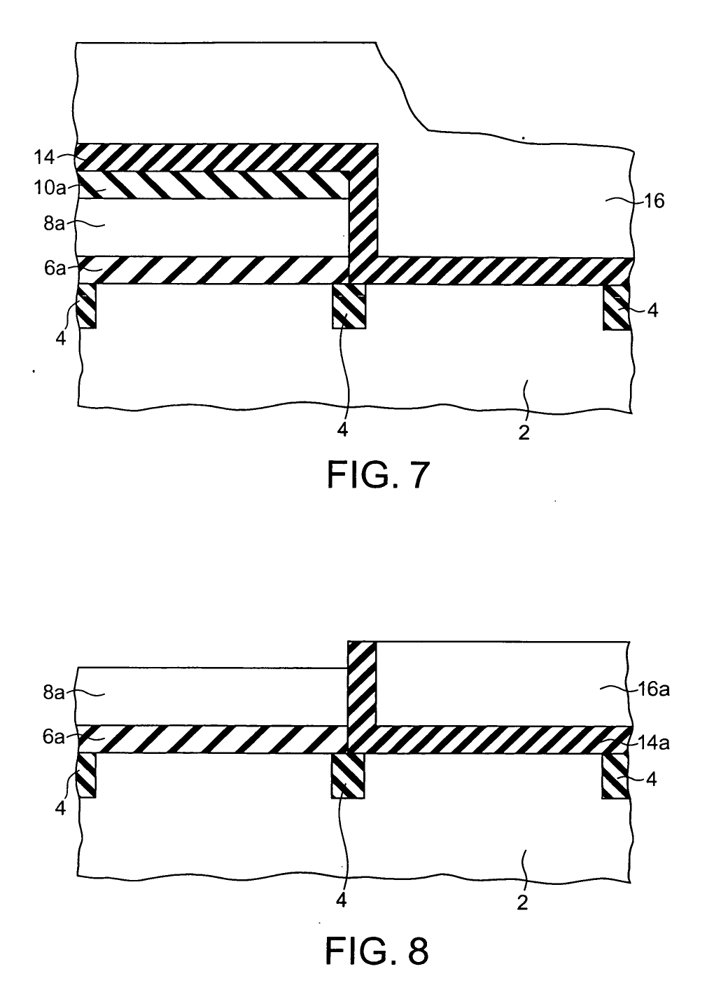

Subsequently, a gate electrode material film 16 of, for example, polycrystalline silicon is formed to cover the insulating film 14 (FIG. 7). Thereafter, the gate electrode material film 16 is flattened by CMP to leave a gate electrode material film 16a only on the second device region (FIG. 8). Then, the insulating film 14 only on the insulating film 10a is removed, thereby leaving an insulating film 14a on the second device region. Thereafter, the insulating film 10a having served as a stopper during CMP is removed (FIG. 8). The insulating film 14 and the insulating film 10a are removed by wet etching or dry etching.

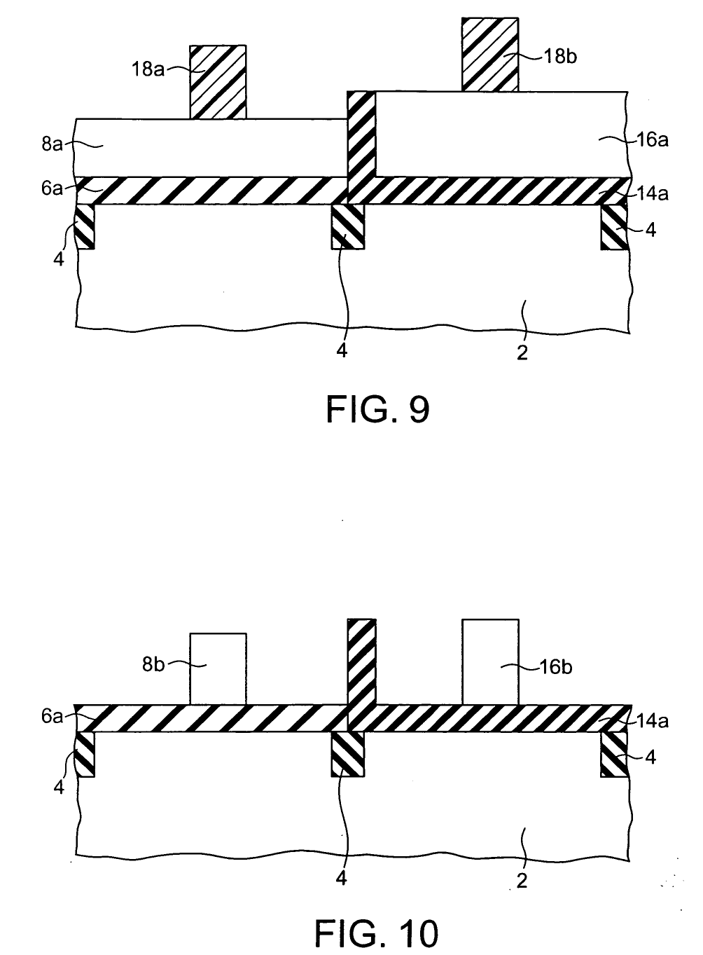

Then, a resist pattern 18a of a photoresist and a resist pattern 18b of a photoresist are formed on the gate electrode material film 8a and the gate electrode material film 16a on the first and the second device regions, respectively (FIG. 9).

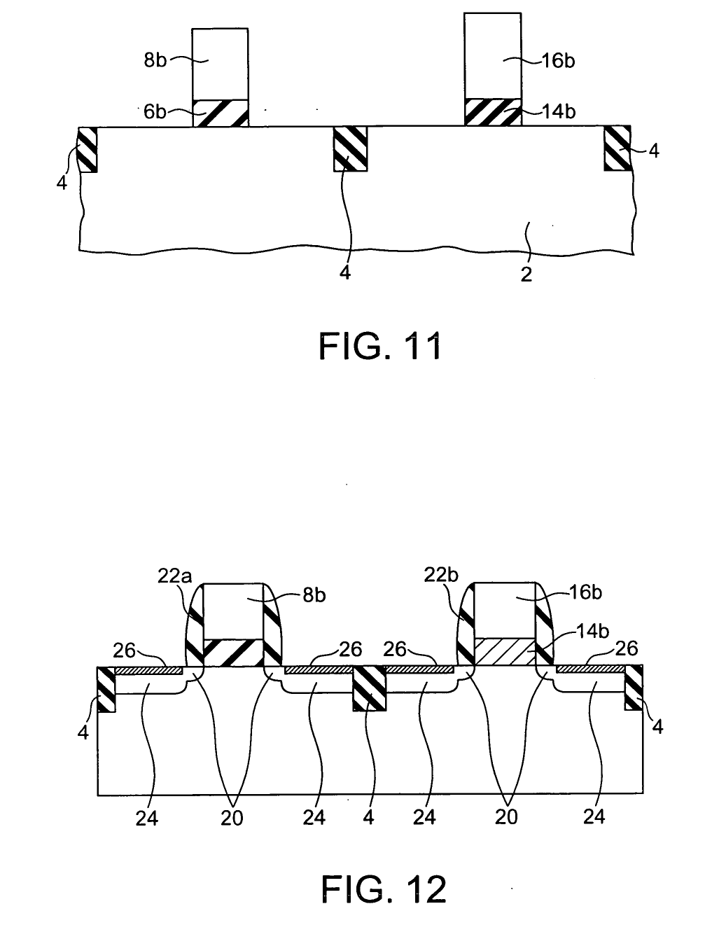

Thereafter, the gate electrode material film 8a and the gate electrode material film 16a are patterned by dry etching using the resist pattern 18a and the resist pattern 18b as masks, respectively, to form a gate electrode 8b on the first device region and a gate electrode 16b on the second device region (FIG. 10). Subsequently, the insulating film 6a and the insulating film 14a are etched by wet etching to form a gate insulating film 6b in the first device region and a gate insulating film 14b in the second device region (FIG. 11). At this time, the gate electrodes 8b and 16b of, for example, polycrystalline silicon, are hardly etched.

Then, as shown in FIG. 12, an impurity is implanted into the first and the and second device regions using the gate electrodes 8b and 16b as masks and the implanted impurity is activated to form extension layers 20. Thereafter, sidewalls 22a of an insulating material is formed at the side portions of the gate insulating film 6b and the gate electrode 8b, and sidewalls 22b of an insulating material is formed at the side portions of the gate insulating film 14b and gate electrode 16b. Subsequently, an impurity is implanted into the first and second device regions, and the implanted impurity is activated, thereby forming source and drain regions 24, of which the junction depth with the semiconductor substrate 2 is deeper and the impurity concentration is higher than those of the extension layers 20. Then, silicidation is performed on the surfaces of the source and drain regions 24 in a self-aligned manner to form salicide layers 26. As a result, MOS transistors can be formed on the same substrate, which include gate insulating films 6b and 14b of different materials.

During the manufacturing process, the surfaces of the gate insulating films 6b and 14b never contact the photoresist. Accordingly, the respective interfaces between the gate insulating film 6b and 14b and the gate electrode 8b and 16b are in a good condition. Therefore, the device characteristics cannot be degraded.

In this embodiment, both the insulating film 6 and the insulating film 14 are formed of HfSiON. However, since the insulating film 6 is formed before the insulating film 14, the Hf concentration of the insulating film 6 should be lower than that of the insulating film 14 in order to prevent the crystallization of HfSiON. The reason for this is that the thickness of an HF-containing material may vary when repeatedly heated.

Generally, an MOSFET including a gate insulating film formed of HfSiON with a low Hf concentration is used for a CPU, a logic circuit, etc., since the operation speed thereof is high. On the other hand, an MOSFET including a gate insulating film formed of HfSiON with a high Hf concentration is used for a memory, etc., since leak current thereof can be curbed.

The insulating films 6 and 14 can be formed of, besides HfSiON, the same high-k material containing the same metal element. However, since the heat resistance of a high-k material in which the concentration of metal element is high is generally not so good, a high-k material with a high metal-element concentration should be used to form the insulating film 14, which is formed later. The high-k material can be HfO₂, ZrO₂, Al₂O₃, La₂O₃, Ta₂O₅, Y₂O₃ and a silicate of these materials, and an aluminate of these materials.

When the insulating films 6 and 14 are formed of difference materials, one with a high heat resistance should be formed first. For example, when one of the insulating film 6 and 14 is formed of HfSiON, the other insulating film can be formed of a high-k material such as HfO₂, ZrO₂, Al₂O₃, La₂O₃, Ta₂O₅, Y₂O₃ and a silicate of these materials, and an aluminate of these materials. In such a case, it is preferable that the insulating film formed of Al₂O₃ or La₂O₃, the heat resistance of which is higher than that of HfSiON, be formed before the insulating film formed of HfSiON.

A gate insulating film formed of ZrO₂ has a low leak current property. The thickness of a gate insulating film formed of La₂O₃ can be made very thin. A gate insulating film formed of Al₂O₃ is thermally stable since Al₂O₃ is hardly crystallized. A gate insulating film formed of a silicate material is superior in thermal stability and mobility. A gate insulting film formed of an aluminate is superior in thermal stability.

### Second Embodiment

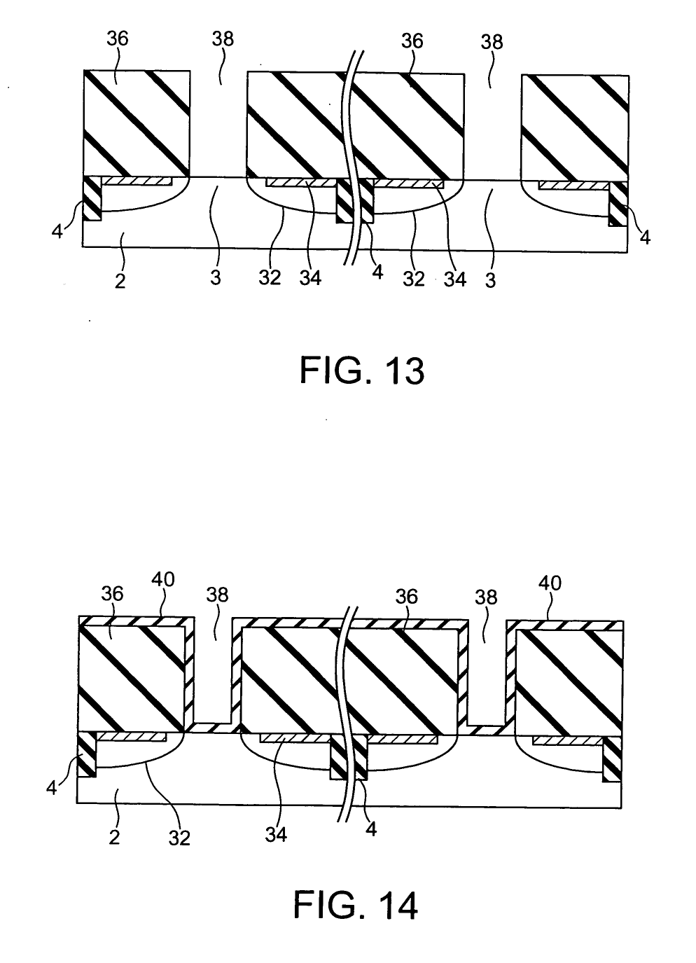

Next, a method of manufacturing a semiconductor device according to the second embodiment of the present invention will be described with reference to FIGS. 13 to 20, which are sectional views showing the steps of the manufacturing method in this embodiment. In the manufacturing method according to this embodiment, MOSFETs each including a gate insulating film a different material can be formed on the substrate, and the gate insulating films and gate electrodes can be formed by the damascene method.

First, as shown in FIG. 13, first and second device regions isolated by device isolation regions 4 are formed on a semiconductor substrate 2. In each of the first and second device regions, a dummy gate electrode (not shown) of polycrystalline silicon is formed on a region 3 to serve as a channel, and source and drain regions 32 are formed at both sides of the dummy gate electrode. Suicide layers 34 are formed by performing silicidation on the surface of the source and drain regions 32. Thereafter, an interlayer insulating film 36 of TEOS (Tetra-Ethyl-Ortho-Silicate) is formed on the semiconductor substrate 2, and then the dummy gate electrodes of polycrystalline silicon are removed, thereby forming openings 38 through the interlayer insulating film 36 on channel regions 3 of the first and second device regions (FIG. 13). At this time, at the bottoms of the openings 38 in the first and second device regions, regions to become channels 3 are exposed.

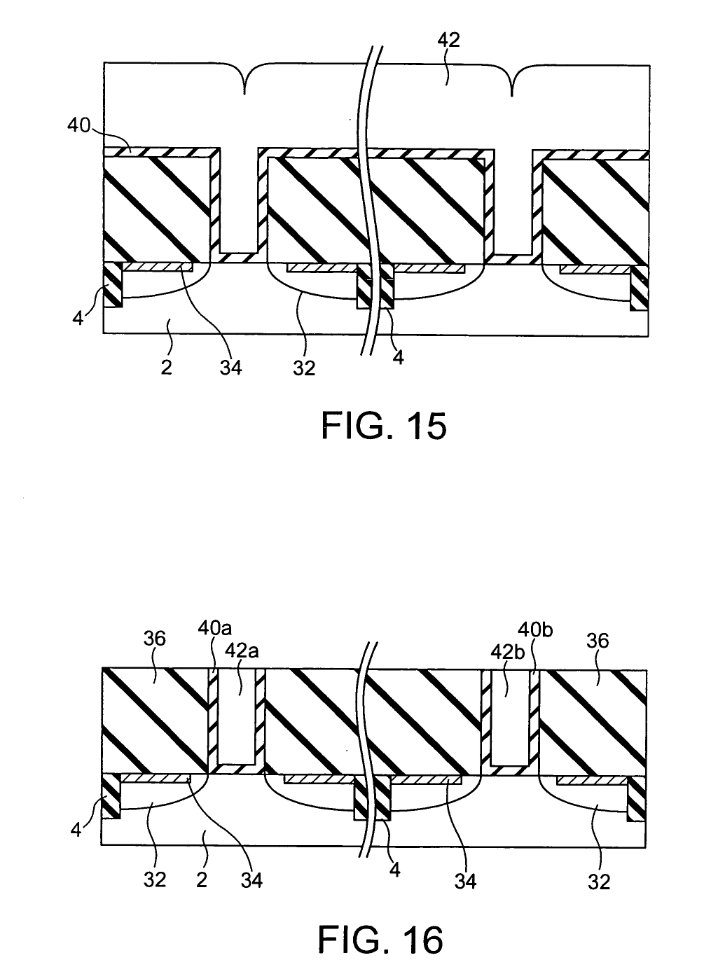

Next, as shown in FIG. 14, a gate insulating material is deposited to form an insulating film 40 at the bottom and side portions of the openings 38. Subsequently, a film 42 of a gate electrode material, for example polycrystalline silicon, is deposited to fill in the openings 38 (FIG. 15).

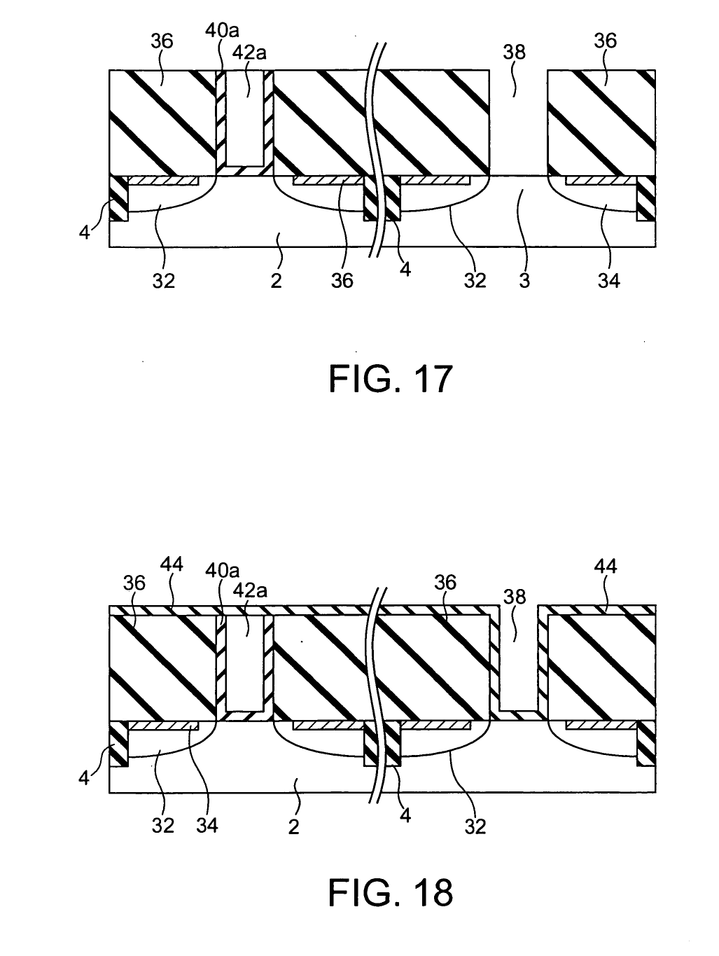

Thereafter, the polycrystalline silicon film 42 and the insulating film 40 are etched by CMP until the interlayer insulating film 36 is exposed, thereby forming a gate insulating film 40a and a gate electrode 42a in the opening 38 of the first device region, and forming a dummy gate insulating film 40b and a gate electrode 42b in the opening of the second device region (FIG. 16). Subsequently, the dummy gate insulating film 40b and the gate electrode 42b in the second device region are removed by PEP (Photo-Engraving Process), thereby forming an opening 38 again in the second device region (FIG. 17). At this time, a region to become a channel 3 of the second device region is exposed at the bottom of the opening 38.

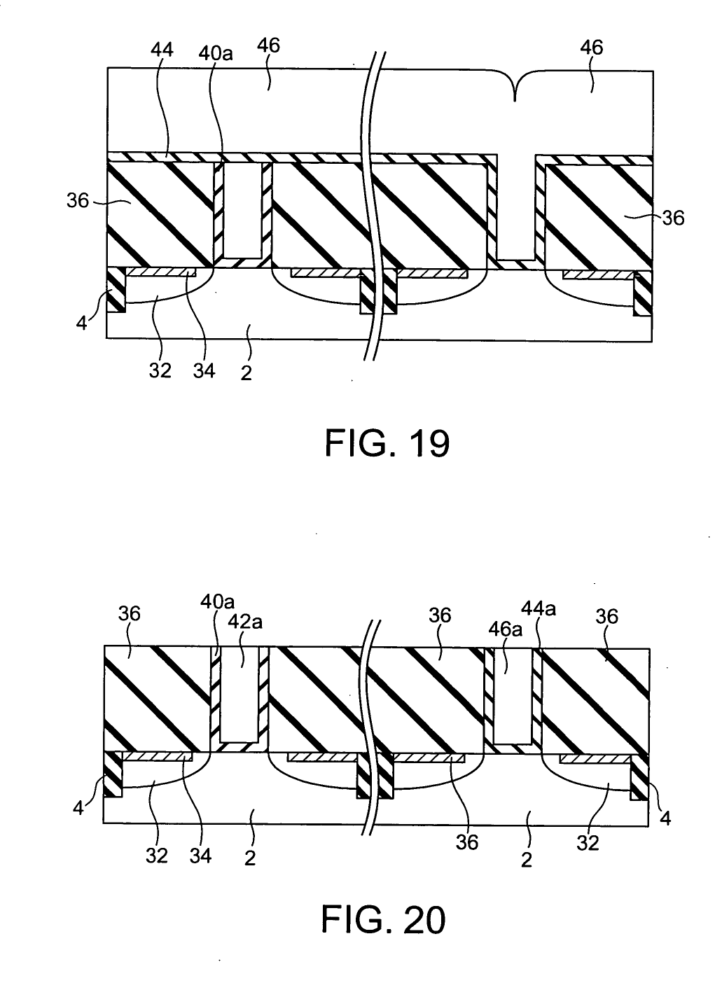

Then, a gate insulating material, which is different from the material of the insulating film 40, is deposited to form an insulating film 44 at the bottom and side portions of the opening 38 in the second device region (FIG. 18). Subsequently, a film 46 of a gate electrode material, for example polycrystalline silicon, is deposited to fill in the opening 38 in the second device region (FIG. 19). Then, the polycrystalline silicon film 46 and the insulating film 44 are etched by CMP until the interlayer insulating film 36 is exposed to form a gate insulating film 44a and a gate electrode 46a in the opening 38 in the second device region (FIG. 20). Thereafter, contact holes (not shown) connecting to the source and drain regions 32 and 34 are formed through the interlayer insulating film 36, and the contact holes are filled with an electrode material, thereby forming source and drain electrodes to complete the transistor.

During the aforementioned manufacturing process, the surfaces of the gate insulating films 40a and 44a never contact the photoresist. Accordingly, the respective interfaces between the gate insulating films 40a and 44a and the gate electrodes 42a and 46a are in a good condition. As a result, the device characteristics are hardly degraded.

As in the case of the first embodiment, both the gate insulating film 40a and the gate insulating film 44a can be formed of HfSiON. In this case, since the gate insulating film 40a is formed before the gate insulating film 44a, the Hf concentration of the gate insulating film 40a should be lower than that of the gate insulating film 44a in order to prevent the crystallization of HfSiON.

Generally, an MOSFET including a gate insulating film formed of HfSiON with a low Hf concentration is used for a CPU, a logic circuit, etc., since the operation speed thereof is high. On the other hand, an MOSFET including a gate insulating film formed of HfSiON with a high. Hf concentration is used for a memory, etc., since leak current thereof can be curbed.

The insulating films 40 and 44 can be formed of, besides HfSiON, the same high-k material containing the same metal element. However, since the heat resistance of a high-k material in which the concentration of metal element is high is generally not so good, a high-k material with a high metal-element concentration should be used to form the insulating film 44, which is formed later. The high-k material can be HfO₂, ZrO₂, Al₂O₃, La₂O₃, Ta₂O₅, Y₂O₃ and a silicate of these materials, and an aluminate of these materials.

When the insulating films 40 and 44 are formed of difference materials, one with a high heat resistance should be formed first. For example, when one of the insulating film 40 and 44 is formed of HfSiON, the other insulating film can be formed of a high-k material such as HfO₂, ZrO₂, Al₂O₃, La₂O₃, Ta₂O₅, Y₂O₃ and a silicate of these materials, and an aluminate of these materials. In such a case, it is preferable that the insulating film formed of Al₂O₃ or La₂O₃, the heat resistance of which is higher than that of HfSiON, be formed before the insulating film formed of HfSiON.

As described above, according to the embodiments of the present invention, it is possible to form a device including gate insulating films each being formed of a different high-k material, and at the same time to prevent the degradation of device characteristics.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A semiconductor device comprising:
a semiconductor substrate including first and second device regions isolated by device isolation regions;
a first gate insulating film of a high-k material formed in the first device region;
a first gate electrode formed on the first gate insulating film;
first source and drain regions formed at both sides of the first gate electrode in the first device region;
a second gate insulating film of a high-k material which is different from the high-k material of the first gate insulating film, the second gate insulating film being formed in the second device region;
a second gate electrode formed on the second gate insulating film; and
second source and drain regions formed at both sides of the second gate electrode in the second device region.

2. The semiconductor device according to claim 1, wherein the first and second gate insulating films are formed of HfSiON with different Hf concentrations.

3. The semiconductor device according to claim 1, wherein the first gate insulating film is formed of HfSiON, and the second gate insulating film is formed of a material selected from the group consisting of HfO₂, ZrO₂, Al₂O₃, La₂O₃, Ta₂O₅, Y₂O₃, and a silicate of any of these materials.

4. The semiconductor device according to claim 1, wherein the first gate insulating film is formed of HfSiON, and the second gate insulating film is formed of an aluminate of a material selected from the group consisting of HfO₂, ZrO₂, Al₂O₃, La₂O₃, Ta₂O₅, and Y₂O₃.

5. A semiconductor device comprising:
a semiconductor substrate including first and second device regions isolated by device isolation regions;
a first channel region formed in the first device region;
first source and drain regions provided at both sides of the first channel region in the first device region;
a first interlayer insulating film covering the first source and drain regions but including a first opening which is provided above the first channel region so as to expose the first channel region at a bottom thereof;
a first gate insulating film of a high-k material provided at the bottom and side portions of the first opening;
a first gate electrode covering the first gate insulating film in the first opening;
a second channel region provided in the second device region;
second source and drain regions provided at both sides of the second device region in the second channel region;
a second interlayer insulating film covering the second source and drain regions but including a second opening which is provided above the second channel region so as to expose the second channel region at a bottom thereof;
a second gate insulating film of a high-k material which is different from the high-k material of the first gate insulating film, the second gate insulating film being provided at the bottom and side portions of the second opening; and
a second gate electrode covering the second gate insulating film in the second opening.

6. The semiconductor device according to claim 5, wherein the first and second gate insulating films are formed of HfSiON with different Hf concentrations.

7. The semiconductor device according to claim 5, wherein the first gate insulating film is formed of HfSiON, and the second gate insulating film is formed of a material selected from the group consisting of HfO₂, ZrO₂, Al₂O₃, La₂O₃, Ta₂O₅, Y₂O₃, and a silicate of any of these materials.

8. The semiconductor device according to claim 5, wherein the first gate insulating film is formed of HfSiON, and the second gate insulating film is formed of an aluminate of a material selected from the group consisting of HfO₂, ZrO₂, Al₂O₃, La₂O₃, Ta₂O₅, and Y₂O₃.

9. A method of manufacturing a semiconductor device comprising:
forming a first insulating film of a high-k material on first and second device regions of a semiconductor substrate which are isolated by device isolation regions;
forming a first electrode material film on the first insulating film;
forming a second insulating film on the first electrode material film;
removing the second insulating film, the first electrode material film, and the first insulating film on the second device region;
forming a third insulating film of a high-k material, which is different from the high-k material of the first insulating film, on the second device region;
depositing a second gate electrode material film on the first and second device region;
removing the second gate electrode material film and the second insulating film on the first device region by flattening the second gate electrode material film;
forming first and second gate electrodes by patterning the first and second gate electrode material films; and
forming first and second gate insulating films by patterning the first and third insulating films using the first and second gate electrodes as masks.

10. The method of manufacturing a semiconductor device according to claim 9, wherein the first and second gate insulating films contain an identical metal element, and a metal element concentration of the first gate insulating film is lower than that of the second gate insulating film.

11. The method of manufacturing a semiconductor device according to claim 9, wherein the first and second gate insulating films are formed of HfSiON with different Hf concentrations.

12. The method of manufacturing a semiconductor device according to claim 11, wherein the Hf concentration of the first gate insulating film is lower than that of the second gate insulating film.

13. The method of manufacturing a semiconductor device according to claim 9, wherein the first gate insulating film is formed of HfSiON, and the second gate insulating film is formed of a material selected from the group consisting of HfO₂, ZrO₂, Al₂O₃, La₂O₃, Ta₂O₅, Y₂O₃, a silicate of any of these materials, and an aluminate of any of these materials.

14. The method of manufacturing a semiconductor device according to claim 9, wherein the first gate insulating film is formed of a material having a higher heat resistance as compared to the second gate insulating film.

15. A method of manufacturing a semiconductor device comprising:
forming first and second dummy gate electrodes on first and second device regions of a semiconductor substrate which are isolated by device isolation regions;
forming first source and drain regions at both sides of the first dummy gate electrode in the first device region, and at the same time forming second source and drain regions at both sides of the second dummy gate electrode in the second device region;
depositing an interlayer insulating film to cover the first and second device region;
forming first and second opening portions reaching the first and second device regions through the interlayer insulating film by removing the first and second dummy gate electrodes;
forming first gate insulating film at a bottom and side portions of the first opening portion;
forming a first gate electrode covering the first gate insulating film in the first opening portion;
forming a second gate insulating film at a bottom and side portions of the second opening portion; and
forming a second gate electrode covering the second gate insulating film in the second opening portion.

16. The method of manufacturing a semiconductor device according to claim 15, wherein the first and second gate insulating films contain an identical metal element, and a metal element concentration of the first gate insulating film is lower than that of the second gate insulating film.

17. The method of manufacturing a semiconductor device according to claim 15, wherein the first and second gate insulating films are formed of HfSiON with different Hf concentrations.

18. The method of manufacturing a semiconductor device according to claim 17, wherein the Hf concentration of the first gate insulating film is lower than that of the second gate insulating film.

19. The method of manufacturing a semiconductor device according to claim 15, wherein the first gate insulating film is formed of HfSiON, and the second gate insulating film is formed of a material selected from the group consisting of HfO₂, ZrO₂, Al₂O₃, La₂O₃, Ta₂O₅, Y₂O₃, a silicate of any of these materials, and an aluminate of any of these materials.

20. The method of manufacturing a semiconductor device according to claim 15, wherein the first gate insulating film is formed of a material having a higher heat resistance as compared to the second gate insulating film.
